(19) United States
(12) Patent Application Publication
(10) Pub. No.: US 2016/0218152 A1
(43) Pub. Date: Jul. 28, 2016

(54) Metal Mesh Touch Screen Structure and Methods for Producing the Same

(71) Applicant: EverDisplay Optronics (Shanghai) Limited, Shanghai (CN)

(72) Inventors: Yuh-Wey Lin, Shanghai (CN); Juan Du, Shanghai (CN)

(21) Appl. No.: 14/991,002

(22) Filed: Jan. 8, 2016

(30) Foreign Application Priority Data
Jan. 26, 2015 (CN) 201510039240.7

(51) Int. Cl. H01L 27/32; H01L 51/52; H01L 51/56; G06F 3/047

(52) U.S. Cl. CPC H01L 27/323; G06F 3/047; H01L 27/3246; H01L 51/5246; H01L 51/56; G06F 2203/04103; H01L 2227/323

(57) ABSTRACT

A metal mesh touch screen structure includes an active matrix organic light-emitting diode (AMOLED) structural layer, a pixel layer, a packaging layer, a bonding layer, and a touch layer arranged in sequence. The pixel layer includes a pixel define layer with a first pattern. The bonding layer includes a metal mesh layer with a second pattern. The first pattern is disposed corresponding to the second pattern. The Moire effect in a touch screen using metal meshes can effectively be avoided by the corresponding disposition of the first and second patterns. In another example, the metal mesh layer is disposed on the AMOLED structural layer. Methods for producing the metal mesh touch screen structure are also disclosed.

### BACKGROUND OF THE INVENTION

The present invention relates to the field of touch screens, more particularly, to a metal mesh touch screen structure for eliminating Moire effect of the metal mesh touch screen and methods for producing the metal mesh touch screen structure.

Metal meshes have been used in touch screen structures to replace indium tin oxide for the purposes of solving two major problems in touch panels using indium tin oxide. One of the two major problems is the optical problem of application of indium tin oxide in glass transducers. The indium tin oxide causes a reduction of the transmittance, whereas the metal meshes in the form of a lattice will not cause any loss of transmittance if completely matched with the pixel define layers of an active matrix organic light-emitting diode (AMOLED). The other major problem is the excessively high sheet resistance. In the conventional deposition technique using indium tin oxide, the sheet resistance of a glass substrate can be as high as 50 ohm/s. Although the metal meshes are made of metal material, the lattice has 250 holes/inch² and has a wire width of 5 μm, the original sheet resistance value (50 ohm/s) must recalculated as an equivalent sheet resistance by stimulation software. Namely, although the equivalent sheet resistance is 50 ohm/s, the actually measured sheet resistance is 30 ohm/s or even smaller, such that the metal meshes can be used to replace indium tin oxide in terms of sheet resistance.

However, in use of a metal mesh touch panel, the lattice structure generates a Moire effect on the display panel. Moire effect (also known as Moire pattern or ripples) is a visual effect created while seeing a set of lines (or points) overlaid with another set of lines (or points). The sizes, corners, or spacings of the two sets of lines (or points) are different from each other. The pattern is visible to the eyes and is not acceptable to the user. When in use, the metal meshes and the pixel define layers create a Moire effect, and there are two particularly serious situations of Moire effect. One of the situations occurs when the metal meshes are at a particular angle to the pixel define layers, as shown in FIG. 1 illustrating the Moire effect created in the case the metal meshes are at the particular angle to the pixel define layers. The other situation occurs when the metal meshes are parallel to the pixel define layers. The metal meshes and the pixel define layers form periodic stripes and, thus, create a Moire effect, as shown in FIG. 2 illustrating the metal meshes parallel to the pixel define layers.

### BRIEF SUMMARY OF THE INVENTION

An objective of the present invention is to overcome the drawbacks of the prior art by providing a metal mesh touch screen structure and methods for producing the metal mesh touch screen structure, thereby fixing the problem of Moire effect resulting from using metal meshes to produce the metal mesh touch screen.

In a first aspect, the present invention provides a metal mesh touch screen structure including an active matrix organic light-emitting diode structural layer, a pixel layer, a packaging layer, a bonding layer, and a touch layer arranged in sequence. The pixel layer includes a pixel define layer with a first pattern. The bonding layer includes a metal mesh layer with a second pattern. The first pattern is disposed corresponding to the second pattern.

By the corresponding disposition of the metal mesh layer with the second pattern and the pixel define layer of the pixel layer with the first pattern, the metal mesh layer and the pixel define layer are aligned to effectively eliminate the Moire effect in a touch screen using metal meshes. By matching the second pattern of the metal mesh layer with the first pattern of the pixel define layer, the metal mesh layer is completely within the pixel define layer to avoid the visual Moire effect.

In an example, the metal mesh layer is formed in the bonding layer and is disposed on an upper surface of the packaging layer. By disposing the metal mesh layer on the upper surface of the packaging layer (and, thus, on the back side of the AMOLED), the alignment tolerance is smaller than 10 μm to reduce the match error between the second pattern of the metal mesh layer with the first pattern of the pixel define layer, reliably eliminating the Moire effect.

In another example, the metal mesh layer is disposed on an upper surface of the bonding layer and is located in the touch layer.

The pixel define layer comprises a plurality of pixel define patterns. Each of the plurality of pixel define patterns has a first width. The metal mesh layer has a plurality of metal mesh patterns. Each of the plurality of metal mesh patterns has a second width. The first width is larger than the second width.

The first width can be 18-22 μm, and the second width can be 4-6 μm.

In a second aspect, a metal mesh touch screen structure comprises an active matrix organic light-emitting diode structural layer, a pixel layer, a packaging layer, a bonding layer, and a touch layer arranged in sequence. The pixel layer includes a pixel define layer with a first pattern. A metal mesh layer with a second pattern is disposed on the active matrix organic light-emitting diode structural layer. The first pattern is disposed corresponding to the second pattern.

In an example, the metal mesh layer is mounted between the active matrix organic light-emitting diode structural layer and the pixel layer and is disposed on an upper surface of the active matrix organic light-emitting diode structural layer. By disposing the metal mesh layer between the pixel layer and the AMOLED structural layer (and, thus, on the inner side of the AMOLED), the alignment tolerance is smaller than 10 μm to reduce the match error between the second pattern of the metal mesh layer with the first pattern of the pixel define layer, reliably eliminating the Moire effect.

The pixel define layer comprises a plurality of pixel define patterns. Each of the plurality of pixel define patterns has a first width. The metal mesh layer has a plurality of metal mesh patterns. Each of the plurality of metal mesh patterns has a second width. The first width is larger than the second width.

The first width can be 18-22 μm, and the second width can be 4-6 μm.

In a third aspect, a method for producing a metal mesh touch screen structure includes:

providing an active matrix organic light-emitting diode structure;

forming a pixel layer on the active matrix organic light-emitting diode structure, wherein the pixel layer comprises a first pattern;

forming a packaging layer on the pixel layer;

forming a metal mesh layer on the packaging layer, wherein the metal mesh layer comprises a second pattern, and the second pattern is disposed corresponding to the first pattern; and

bonding a touch layer to the metal mesh layer.

The pixel define layer comprises a plurality of pixel define patterns. Each of the plurality of pixel define patterns has a first width. The metal mesh layer has a plurality of metal mesh patterns. Each of the plurality of metal mesh patterns has a second width. The first width is larger than the second width.

In a fourth aspect, a method for producing a metal mesh touch screen structure includes:

providing an active matrix organic light-emitting diode structure;

forming a metal mesh layer and a pixel layer on the active matrix organic light-emitting diode structure, wherein the pixel layer comprises a first pattern, the metal mesh layer comprises a second pattern, and the first pattern is disposed corresponding to the second pattern;

forming a packaging layer on the pixel layer; and

bonding a touch layer to the packaging layer.

The pixel define layer comprises a plurality of pixel define patterns. Each of the plurality of pixel define patterns has a first width. The metal mesh layer has a plurality of metal mesh patterns. Each of the plurality of metal mesh patterns has a second width. The first width is larger than the second width.

The present invention will become clearer in light of the following detailed description of illustrative embodiments of this invention described in connection with the drawings.

### DESCRIPTION OF THE DRAWINGS

FIG. 1 is a diagrammatic view illustrating Moire effect resulting from a particular angle between metal meshes and pixel define layers according to the prior art.

FIG. 2 is a diagrammatic view illustrating Moire effect resulting from a parallel arrangement between metal meshes and pixel define layers according to the prior art.

FIG. 3 is a diagrammatic view of a metal mesh layer and a pixel define layer of a pixel layer according to the present invention, with the metal mesh layer and the pixel define layer having an identical period to eliminate the Moire effect.

FIG. 4 is a diagrammatic view of a metal mesh touch screen structure of an embodiment according to the present invention, with the metal mesh layer disposed in a touch layer.

FIG. 5 is a diagrammatic view of a metal mesh touch screen structure of another embodiment according to the present invention, with a Moire effect created and with the metal mesh layer disposed in a touch layer.

FIG. 6 is a diagrammatic view of a metal mesh touch screen structure of a further embodiment according to the present invention, with the metal mesh layer disposed on a packaging layer.

FIG. 7 is a diagrammatic view of a metal mesh touch screen structure of still another according to the present invention, with the metal mesh layer disposed between an AMOLED structural layer and a pixel layer.

FIG. 8 is a block diagram illustrating a method for producing a metal mesh touch screen structure of a first example according to the present invention.

FIG. 9 is a block diagram illustrating a method for producing a metal mesh touch screen structure of a second example according to the present invention.

### DETAILED DESCRIPTION OF THE INVENTION

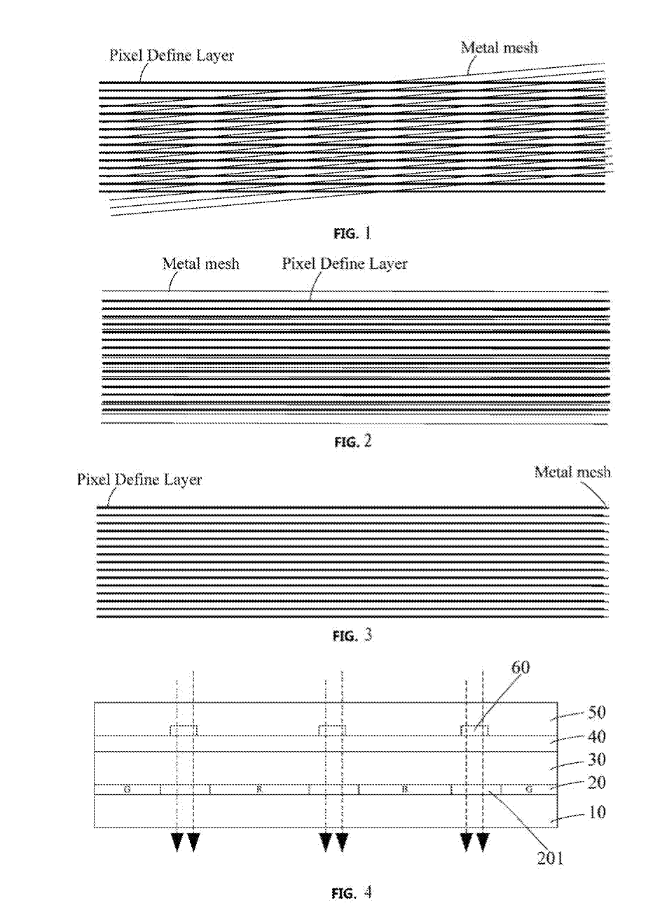

FIG. 3 is a diagrammatic view illustrating a corresponding disposition of a metal mesh and a pixel define layer of a pixel layer according to the present invention, such that the metal mesh layer and the pixel define layer are aligned with each other and have identical period to eliminate the Moire effect. In a metal mesh touch screen structure and methods for producing the metal mesh touch screen structure, by using metal mesh layer and the pixel define layer of the pixel layer having identical period, the metal mesh layer and the pixel define layer of the pixel layer are disposed corresponding to each other to eliminate the Moire effect. A width of the pixel define layer is larger than a width of the metal mesh, such that the metal meshes are respectively disposed in the pixel define patterns without generating the visual Moire effect, effectively reducing the Moire pattern resulting from overlapping of the metal meshes. The metal mesh touch screen structure and the methods for producing the metal mesh touch screen structure will now be set forth in connection with the accompanying drawings.

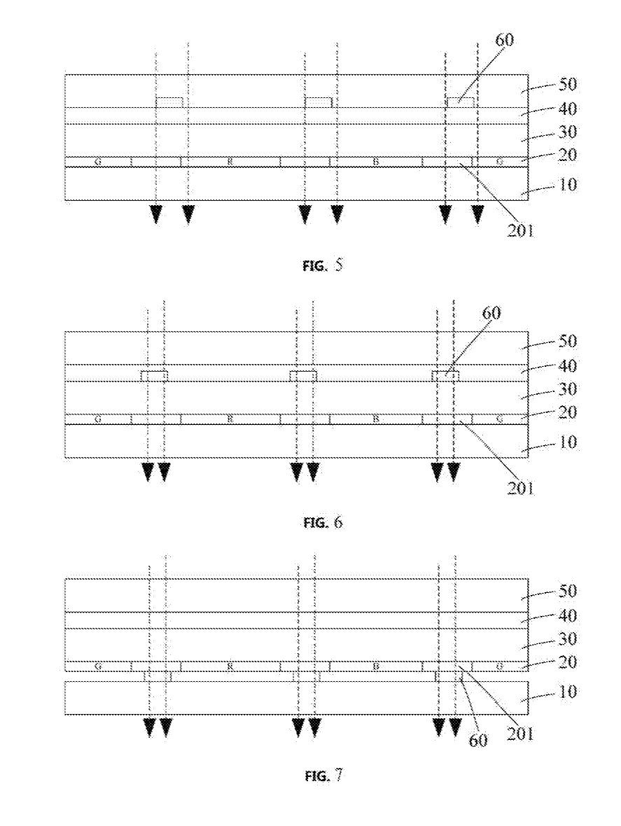

FIG. 4 is a diagrammatic view of a metal mesh touch screen structure of an embodiment according to the present invention, with the metal mesh layer disposed in a touch layer. Specifically, in the embodiment shown in FIG. 4, the metal mesh touch screen structure according to the present invention includes an active matrix organic light-emitting diode (AMOLED) structural layer 10, a pixel layer 20, a packaging layer 30, a bonding layer 40, and a touch layer 50 arranged in sequence. The pixel layer 20 includes a pixel define layer with a first pattern. The pixel define layer in the pixel layer 20 has rod-shaped sections spaced from each other. The pixel define layer includes a plurality of pixel define patterns 201. A red pixel R, a blue pixel B, or a green pixel G is disposed between two adjacent pixel define patterns 201. The bonding layer 40 includes a metal mesh layer having a plurality of metal meshes 60 with a second pattern. The first pattern is disposed corresponding to the second pattern. The term “corresponding” used herein means the range of the second pattern is within the range of the first pattern. The first pattern is the arrangement of the pixel define patterns 201 in the form of spaced rod-shaped sections. The second pattern is the arrangement of the metal meshes 60 in the form of spaced rod-shaped sections. Each metal mesh 60 is disposed within an associated pixel define pattern 201. Corresponding disposition between the metal mesh 60 and the pixel define pattern 201 is, thus, achieved.

In this embodiment, the metal meshes 60 are formed on an upper surface of the bonding layer 40 and are located in the touch layer 50. Each pixel define pattern 201 has a first width, each metal mesh 60 has a second width, and the first width is larger than the second width. This assures each metal mesh 60 is within an associated pixel define pattern 201 after disposition.

The second width of each metal mesh 60 of the metal mesh layer is 4-6 μm, preferably 5 μm. The first width of each pixel define pattern 201 of the pixel layer 20 is 18-22 μm, preferably 20 μm. The metal meshes 60 of the metal mesh layer are disposed in the touch layer 50. Each metal mesh 60 is disposed corresponding to an associated pixel define pattern 201 and is located within the associated pixel define pattern 201. The arrowed phantom lines in FIG. 4 represent the visual effect. Two sightlines on each metal mesh 60 are close to each other, and each metal mesh 60 is located within an associated pixel define pattern 201, such that the visual Moire effect will not be created. FIG. 3 shows the effect of elimination of the Moire effect due to identical period of the metal meshes 60 and the pixel define patterns 201. Theoretically, the Moire effect can be eliminated by setting the periods of the metal meshes 60 and the pixel define patterns 201 to be identical and by disposing the metal meshes 60 within the pixel define patterns 201, respectively. However, in actual practice, the Moire effect could still be created even if the metal meshes 60 are disposed in the touch layer 50. The actual effect is shown in FIG. 5. FIG. 5 is a diagrammatic view of a metal mesh touch screen structure of another embodiment according to the present invention, with a Moire effect created and with the metal mesh layer disposed in the touch layer 50. The embodiment of the metal mesh touch screen structure according to the present invention shown in FIG. 5 will be set forth in details.

As shown in FIG. 5, in the metal mesh touch screen structure according to the present invention, the metal meshes 60 are disposed in the touch layer 50. The touch layer 50 is bonded to the packaging layer 30 by the bonding layer 40. During the bonding process, the alignment tolerance of the touch layer 50 is larger than 10 μm. The second width of each metal mesh 60 is 5 μm. The first width of each pixel define pattern 201 is 20 μm. If the center of each metal mesh 60 is aligned with the center of an associated pixel define pattern 201, the metal mesh 60 and the 10 μm alignment tolerance of the touch layer 50 generated during the bonding process will cause a portion of the metal mesh 60 to extend beyond the associated pixel define pattern 201, creating the Moire effect due to the parallel relation between the metal meshes 60 and the pixel define patterns 201. In the touch screen structure obtained by disposing the metal meshes 60 in the touch layer 50, the metal meshes 60 will become larger and, thus, deviate from the pixel define patterns 201 due to the large alignment tolerance of the touch layer 50, failing to provide good alignment with the pixel define patterns 201. In this case, the visual Moire effect is created. If each metal mesh 60 is disposed in a location adjacent to an end of the associated pixel define pattern 201, the metal mesh 60 will not extend beyond the associated pixel define pattern 201 even if the alignment tolerance is as large as 10 μm. Thus, when the metal meshes 60 are disposed in the touch layer 50, the factor of alignment tolerance must be considered to completely eliminate the Moire effect.

Since the Moire effect could still be created when the metal meshes 60 are disposed in the touch layer 50 (the Moire effect cannot be completely eliminated) and since the factor of alignment tolerance must be considered and, thus, requires higher demands of processes and designs (which are difficult to achieve), it is proposed to dispose the metal meshes 60 in or on an active matrix organic light-emitting diode (AMOLED) structure. Since the processing tolerance in and on the structure of the AMOLED is smaller than 10 μm in the current technology, the demand of identical period of the metal meshes and the pixel define layers can be fulfilled. Furthermore, the metal meshes 60 are not in the touch layer 50, such that the alignment tolerance of the touch layer 50 will not adversely affect the position of the metal meshes 60. Thus, the disposition problem of the metal meshes 60 in the touch layer 50 can be solved.

FIG. 6 is a diagrammatic view of a metal mesh touch screen structure of a further embodiment according to the present invention, with the metal mesh layer disposed on the packaging layer 30. The embodiment of the metal mesh touch screen structure according to the present invention shown in FIG. 6 will be set forth in details. The pixel layer of the metal mesh touch screen structure of this embodiment also include a pixel define layer with a first pattern. The bonding layer includes a metal mesh layer with a second pattern disposed corresponding to the first pattern.

Specifically, in the embodiment shown in FIG. 6, the metal mesh touch screen structure according to the present invention includes an active matrix organic light-emitting diode (AMOLED) structural layer 10, a pixel layer 20, a packaging layer 30, a bonding layer 40, and a touch layer 50 arranged in sequence. The pixel layer 20 includes a pixel define layer with the first pattern. The pixel define layer includes a plurality of pixel define patterns 201. The structure of the pixel define layer in this embodiment is the same as the pixel define layer of FIG. 4. The difference between this embodiment and the embodiment of FIG. 4 is that the metal mesh layer is mounted in the bonding layer 40 and is formed on an upper surface of the packaging layer 30. The metal meshes 60 are disposed on the upper surface of the packaging layer 30, and the bonding layer 40 covers the outer surfaces of the metal meshes 60. The alignment tolerance is smaller than 10 μm by disposing the metal meshes 60 on the packaging layer 30 in a semiconductor process. After disposing the metal meshes 60 on the packaging layer 30, it is easy to assure the metal meshes 60 are correspondingly disposed within the pixel define patterns 201 when it is within the alignment tolerance. The arrowed phantom lines in FIG. 6 represent the visual effect. Two sightlines on each metal mesh 60 are close to each other, and each metal mesh 60 is located within an associated pixel define pattern 201, such that the visual Moire effect will not be created. FIG. 3 shows the effect of elimination of the Moire effect due to identical period of the metal meshes 60 and the pixel define patterns 201.

FIG. 7 is a diagrammatic view of still another embodiment of the metal mesh touch screen structure according to the present invention, with the metal mesh layer disposed between the AMOLED structural layer and the pixel layer. The embodiment of the metal mesh touch screen structure according to the present invention shown in FIG. 7 will be set forth in details.

Specifically, in the embodiment shown in FIG. 7, the metal mesh touch screen structure according to the present invention includes an active matrix organic light-emitting diode (AMOLED) structural layer 10, a pixel layer 20, a packaging layer 30, a bonding layer 40, and a touch layer 50 arranged in sequence. The pixel layer 20 includes a pixel define layer with a first pattern. The pixel define layer in the pixel layer 20 has rod-shaped sections spaced from each other. The pixel define layer includes a plurality of pixel define patterns 201. A red pixel R, a blue pixel B, or a green pixel G is disposed between two adjacent pixel define patterns 201. A metal mesh layer is mounted between the AMOLED structural layer 10 and the pixel layer 20 and includes a plurality of metal meshes 60 with a second pattern. The first pattern is disposed corresponding to the second pattern. The term “corresponding” used herein means the range of the second pattern is within the range of the first pattern. The first pattern is the arrangement of the pixel define patterns 201 in the form of spaced rod-shaped sections. The second pattern is the arrangement of the metal meshes 60 in the form of spaced rod-shaped sections. Each metal mesh 60 is disposed corresponding to an associated pixel define pattern 201. Corresponding disposition between the metal mesh 60 and the pixel define pattern 201 is, thus, achieved. Each pixel define pattern 201 has a first width, each metal mesh layer 60 has a second width, and the first width is larger than the second width. This assures each metal mesh 60 is within an associated pixel define pattern 201 after disposition. The second width of each metal mesh 60 of the metal mesh layer is 4-6 μm, preferably 5 μm.

The first width of each pixel define pattern 201 of the pixel layer 20 is 18-22 μm, preferably 20 μm.

In this embodiment, the metal mesh layer is disposed on the upper surface of the AMOLED structural layer 10 and is mounted between the AMOLED structural layer 10 and the pixel layer 20, as mentioned above. The alignment tolerance is smaller than 10 μm by disposing the metal meshes 60 between the AMOLED structural layer 10 and the pixel layer 20 in a semiconductor process. After disposing the metal meshes 60 on the packaging layer 30, it is easy to assure the metal meshes 60 are disposed within the pixel define patterns 201 when it is within the alignment tolerance. The arrowed phantom lines in FIG. 7 represent the visual effect. Two sightlines on each metal mesh 60 are close to each other, and each metal mesh 60 is located within an associated pixel define pattern 201, such that the visual Moire effect will not be created. FIG. 3 shows the effect of elimination of the Moire effect due to identical period of the metal meshes 60 and the pixel define patterns 201.

By disposing the metal mesh layer on the inner or back side of the AMOLED, since the alignment tolerance in the current processes is smaller than 10 μm, it is assured that the metal meshes 60 and the pixel define patterns 201 in the pixel layer 20 have the same period, and the metal meshes 60 are disposed within the pixel define patterns 201, such that each metal mesh 60 is within an associated pixel define pattern 201, effectively avoiding the Moire effect.

The advantages effects of the metal mesh touch screen structure according to the present invention are that the Moire effect created by metal meshes can be avoided by the correspondingly disposition of the metal meshes 60 and the pixel define patterns 201 of the pixel layer 20. The alignment tolerance is assured to be smaller than 10 μm by disposing the metal meshes 60 on the inner or back side of the AMOLED. The actual positions of the metal meshes 60 are on the packaging layer 30 or between the AMOLED structural layer 10 and the pixel layer 20 to assure the corresponding disposition of the metal meshes 60 and the pixel define patterns 201, effectively eliminating the Moire effect created by the metal meshes 60. The metal mesh touch screen structure using metal meshes also has the advantage of a low equivalent sheet resistance. The receiving and transmitting frequencies are increased in the electrical performance, and the scan time can be increased, increasing the effect of filtering the ambient noise and increasing the linearity performance.

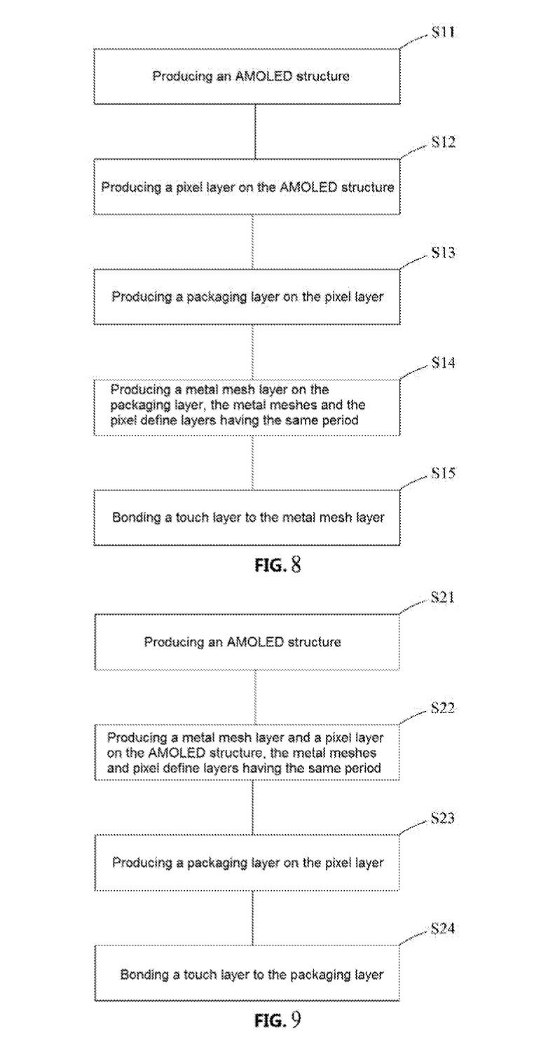

FIG. 8 is a block diagram illustrating a method for producing a metal mesh touch screen structure of a first example according to the present invention.

As shown in FIG. 8, the method for producing a metal mesh touch screen structure of the first example according to the present invention includes providing an active matrix organic light-emitting diode (AMOLED) structure (step S11). With reference to FIG. 6, the AMOLED structure can be produced by an ordinary semiconductor process to obtain an AMOLED structural layer 10. Next, step S12 is carried out.

In step S12, a pixel layer 20 is produced on the AMOLED structural layer 10. The pixel layer 20 includes a pixel define layer with a first pattern. The pixel define layer in the pixel layer 20 has rod-shaped sections spaced from each other. The pixel define layer includes a plurality of pixel define patterns 201. A red pixel R, a blue pixel B, or a green pixel G is disposed between two adjacent pixel define patterns 201. The pixel layer 20 is, thus, obtained. Next, step S13 is carried out.

In step S13, a packaging layer 30 is formed on the pixel layer 20. The pixel layer 20 and the AMOLED structural layer 10 are packaged by the packaging layer 30. Next, step S14 is carried out.

In step S14, a metal mesh layer is formed on the packaging layer 30. The metal mesh layer includes a plurality of metal meshes 60 with a second pattern disposed corresponding to the first pattern, such that each metal mesh 60 is located within an associated pixel define pattern 201 of the pixel layer 20 and is disposed corresponding to the associated pixel define pattern 201. Each pixel define pattern 201 has a first width, each metal mesh layer 60 has a second width, and the first width is larger than the second width. The second width of each metal mesh 60 of the metal mesh layer is 4-6 μm, preferably 5 μm. The first width of each pixel define pattern 201 of the pixel layer 20 is 18-22 μm, preferably 20 μm. By using an ordinary semiconductor process having a tolerance smaller than 10 μm to obtain a metal mesh layer for the purposes of meeting the tolerance demand, each metal mesh 60 of the metal mesh layer is still within an associated pixel define pattern 201 after disposition to effectively eliminate the Moire effect. Next, step S15 is carried out.

In step S15, a touch layer 50 is bonded to the metal mesh layer. Thus, the touch layer 50 is bonded to the metal mesh layer by a bonding layer 40.

A metal mesh touch screen structure is, thus, obtained. The metal mesh touch screen structure using metal meshes 60 has a low equivalent sheet resistance. The receiving and transmitting frequencies are increased in the electrical performance, and the scan time can be increased, increasing the effect of filtering the ambient noise and increasing the linearity performance. The Moire effect created by the metal meshes can be avoided by disposing the metal meshes 60 corresponding to the pixel define patterns 201 of the pixel layer 20. The alignment tolerance is assured to be smaller than 10 μm by disposing the metal meshes 60 on the back side of the AMOLED. The actual positions of the metal meshes 60 are on the packaging layer 30 of the AMOLED to assure the corresponding disposition of the metal meshes 60 and the pixel define patterns 201, effectively eliminating the Moire effect created by the metal meshes 60.

FIG. 9 is a block diagram illustrating a method for producing a metal mesh touch screen structure of a second example according to the present invention.

As shown in FIG. 9, the method for producing a metal mesh touch screen structure of the second example according to the present invention includes providing an active matrix organic light-emitting diode (AMOLED) structure (step S21). With reference to FIG. 7, the AMOLED structure can be produced by an ordinary semiconductor process to obtain an AMOLED structural layer 10. Next, step S22 is carried out.

In step S22, a metal mesh layer and a pixel layer 20 are formed on the AMOLED structural layer 10. The pixel layer 20 includes a pixel define layer with a first pattern. The pixel define layer includes a plurality of pixel define patterns 201. The metal mesh layer includes a plurality of metal meshes 60 with a second pattern, and the first pattern is disposed corresponding to the second pattern. The metal meshes 60 are mounted between the pixel layer 20 and the AMOLED structural layer 10. Each metal mesh 60 is disposed corresponding to an associated pixel define pattern 201 of the pixel layer 20 and is located within the associated pixel define pattern 201. Each pixel define pattern 201 has a first width, each metal mesh layer 60 has a second width, and the first width is larger than the second width. The second width of each metal mesh 60 of the metal mesh layer is 4-6 μm, preferably 5 μm. The first width of each pixel define pattern 201 of the pixel layer 20 is 18-22 μm, preferably 20 μm. By using an ordinary semiconductor process having a tolerance smaller than 10 μm to obtain a metal mesh layer for the purposes of meeting the tolerance demand, each metal mesh 60 of the metal mesh layer is still within an associated pixel define pattern 201 after disposition to effectively eliminate the Moire effect. Next, step S23 is carried out.

In step S23, a packaging layer 30 is formed on the pixel layer 20. The pixel layer 20, the metal mesh layer, and the AMOLED structural layer 10 are packaged by the packaging layer 30. Next, step S24 is carried out.

In step S24, a touch layer 50 is bonded to the packaging layer 30. The touch layer 50 is disposed on top of the packaging layer 30 by a bonding layer 40.

A metal mesh touch screen structure is, thus, obtained. The metal mesh touch screen structure using metal meshes 60 has a low equivalent sheet resistance. The receiving and transmitting frequencies are increased in the electrical performance, and the scan time can be increased, increasing the effect of filtering the ambient noise and increasing the linearity performance. The Moire effect created by the metal meshes can be avoided by disposing the metal meshes 60 and the pixel define patterns 201 having the same period. The alignment tolerance is assured to be smaller than 10 μm by disposing the metal meshes 60 on the inner side of the AMOLED. The actual positions of the metal meshes 60 are between the AMOLED structural layer 10 and the pixel layer 20 to assure the corresponding disposition of the metal meshes 60 and the pixel define patterns 201, effectively eliminating the Moire effect created by the metal meshes 60.

Thus since the illustrative embodiments disclosed herein may be embodied in other specific forms without departing from the spirit or general characteristics thereof, some of which forms have been indicated, the embodiments described herein are to be considered in all respects illustrative and not restrictive. The scope is to be indicated by the appended claims, rather than by the foregoing description, and all changes which come within the meaning and range of equivalency of the claims are intended to be embraced therein.

1. A metal mesh touch screen structure comprising an active matrix organic light-emitting diode structural layer, a pixel layer, a packaging layer, a bonding layer, and a touch layer arranged in sequence, wherein the pixel layer includes a pixel define layer with a first pattern, the bonding layer includes a metal mesh layer with a second pattern, and the first pattern is disposed corresponding to the second pattern.

2. The metal mesh touch screen structure according to claim 1, wherein the metal mesh layer is formed in the bonding layer and is disposed on an upper surface of the packaging layer.

3. The metal mesh touch screen structure according to claim 1, wherein the metal mesh layer is disposed on an upper surface of the bonding layer and is located in the touch layer.

4. The metal mesh touch screen structure according to claim 1, wherein the pixel define layer comprises a plurality of pixel define patterns, each of the plurality of pixel define patterns has a first width, and the metal mesh layer has a plurality of metal mesh patterns, each of the plurality of metal mesh patterns has a second width, and the first width is larger than the second width.

5. The metal mesh touch screen structure according to claim 4, wherein the first width is 18-22 μm, and the second width is 4-6 μm.

6. A metal mesh touch screen structure comprising an active matrix organic light-emitting diode structural layer, a pixel layer, a packaging layer, a bonding layer, and a touch layer arranged in sequence, wherein the pixel layer includes a pixel define layer with a first pattern, a metal mesh layer with a second pattern is disposed on the active matrix organic light-emitting diode structural layer, and the first pattern is disposed corresponding to the second pattern.

7. The metal mesh touch screen structure according to claim 6, wherein the metal mesh layer is disposed between the active matrix organic light-emitting diode structural layer and the pixel layer and is disposed on an upper surface of the active matrix organic light-emitting diode structural layer.

8. The metal mesh touch screen structure according to claim 6, wherein the pixel define layer comprises a plurality of pixel define patterns, each of the plurality of pixel define patterns has a first width, the metal mesh layer has a plurality of metal mesh patterns, each of the plurality of metal mesh patterns has a second width, and the first width is larger than the second width.

9. The metal mesh touch screen structure according to claim 8, wherein the first width is 18-22 μm, and the second width is 4-6 μm.

10. A method for producing a metal mesh touch screen structure, comprising:
providing an active matrix organic light-emitting diode structure;
forming a pixel layer on the active matrix organic light-emitting diode structure, wherein the pixel layer comprises a first pattern;
forming a packaging layer on the pixel layer;
forming a metal mesh layer on the packaging layer, wherein the metal mesh layer comprises a second pattern, and the second pattern is disposed corresponding to the first pattern; and
bonding a touch layer to the metal mesh layer.

11. The method for producing a metal mesh touch screen structure according to claim 10, wherein the pixel define layer comprises a plurality of pixel define patterns, each of the plurality of pixel define patterns has a first width, the metal mesh layer has a plurality of metal mesh patterns, each of the plurality of metal mesh pattern has a second width, and the first width is larger than the second width.

12. A method for producing a metal mesh touch screen structure, comprising:
providing an active matrix organic light-emitting diode structure;
providing a metal mesh layer and a pixel layer on the active matrix organic light-emitting diode structure, wherein the pixel layer comprises a first pattern, the metal mesh layer comprises a second pattern, and the first pattern is disposed corresponding to the second pattern;
forming a packaging layer on the pixel layer; and
bonding a touch layer to the packaging layer.

13. The method for producing a metal mesh touch screen structure according to claim 12, wherein the pixel define layer comprises a plurality of pixel define patterns, each of the plurality of pixel define patterns has a first width, the metal mesh layer has a plurality of metal mesh patterns, each of the plurality of metal mesh pattern has a second width, and the first width is larger than the second width.
